(19) United States
(12) Patent Application Publication
(10) Pub. No.: US 2026/0239928 A1
(43) Pub. Date: Aug. 13, 2026

(54) INTERCONNECT STACK AND A METHOD FOR FORMING THE SAME

(71) Applicant: JCET STATS ChipPAC Korea Limited, Incheon (KR)

(72) Inventors: MinSung LEE, Incheon (KR); YeoJun YUN, Incheon (KR); HeeSoo LEE, Incheon (KR)

(21) Appl. No.: 19/533,276

(22) Filed: Feb. 8, 2026

(30) Foreign Application Priority Data
Feb. 8, 2025 (CN) 202510141616.9

(51) Int. Cl. H10P 74/20; H10P 58/00; H10W 72/00; H10W 80/00; H10W 90/26

(52) U.S. Cl. CPC H10P 74/203; H10P 58/00; H10W 72/07236; H10W 80/314; H10W 80/327; H10W 80/334; H10W 90/26

(57) ABSTRACT

A method for forming an interconnect stack comprises: providing a first semiconductor wafer having a plurality of first semiconductor units each having a set of first conductive interconnect structures extending therethrough the first semiconductor wafer; providing a second semiconductor wafer having a plurality of second semiconductor units each having a set of second conductive interconnect structures extending therethrough; singulating the second semiconductor wafer into second semiconductor dice; aligning vertically each of the second semiconductor dice with one of the first semiconductor units; bonding each of the second semiconductor dice with one of the first semiconductor units by using hybrid bonding; singulating the first semiconductor wafer into first semiconductor dice to form bilayer interconnect sub-stacks; testing each of the plurality of bilayer interconnect sub-stacks to sort out qualified bilayer interconnect sub-stacks; and bonding two of the qualified bilayer interconnect sub-stacks to form the interconnect stack.

### TECHNICAL FIELD

The present application generally relates to semiconductor technology, and more particularly, to an interconnect stack and a method for forming the same.

### BACKGROUND OF THE INVENTION

The semiconductor industry is constantly faced with complex integration challenges as consumers want their electronics to be smaller, faster and higher performance with more and more functionalities packed into a single device. To meet these requirements, electronic modules such as wafers or chips may be stacked and bonded together to form a multilayer electronic package with multiple functionalities.

Recently, hybrid bonding is an advanced interconnection technology which bonds stacked electronic modules together to form an interconnect stack with enhanced density, thereby resulting in high performance, small form factors and lower consumption of the devices. However, for an interconnect stack incorporating multiple layers of electronic modules, the stacking and bonding of various layers of electronic modules may cause potential challenges of alignment precision, which may adversely affect a yield of the interconnect stacks and result in a higher cost.

Therefore, a need exists for a method for forming an interconnect stack with an improved yield and a reduced cost.

### SUMMARY OF THE INVENTION

An objective of the present application is to provide a method for forming an interconnect stack with an improved yield and a reduced cost.

According to an aspect of the present application, a method for forming an interconnect stack is provided. The method comprises: providing a first semiconductor wafer having at its top side a first top dielectric layer and at its bottom side a first bottom dielectric layer, wherein the first semiconductor wafer comprises a plurality of first semiconductor units each having a set of first conductive interconnect structures extending through the first semiconductor wafer; providing a second semiconductor wafer having at its top side a second top dielectric layer and at its bottom side a second bottom dielectric layer, wherein the second semiconductor wafer comprises a plurality of second semiconductor units each having a set of second conductive interconnect structures extending through the second semiconductor wafer; singulating the plurality of second semiconductor units of the second semiconductor wafer into a plurality of second semiconductor dice; aligning vertically each of the second semiconductor dice with one of the first semiconductor units of the first semiconductor wafer to stack them together; bonding each of the second semiconductor dice with one of the first semiconductor units by using hybrid bonding such that the second top dielectric layer and the set of second conductive interconnect structures of the second semiconductor die are aligned vertically and bonded with the first top dielectric layer and the set of first conductive interconnect structures of the first semiconductor unit, respectively; singulating the plurality of first semiconductor units of the first semiconductor wafer into a plurality of first semiconductor dice such that each of the first semiconductor dice is bonded with one of the second semiconductor dice to form a plurality of bilayer interconnect sub-stacks; testing each of the plurality of bilayer interconnect sub-stacks to sort out qualified bilayer interconnect sub-stacks from the plurality of bilayer interconnect sub-stacks; and bonding at least two of the qualified bilayer interconnect sub-stacks together to form the interconnect stack.

According to another aspect of the present application, a method for forming an interconnect stack is provided. The method comprises: providing a first semiconductor wafer having at its top side a first top dielectric layer and at its bottom side a first bottom dielectric layer, wherein the first semiconductor wafer comprises a plurality of first semiconductor units each having a set of first conductive interconnect structures extending through the first semiconductor wafer; providing a second semiconductor wafer having at its top side a second top dielectric layer and at its bottom side a second bottom dielectric layer, wherein the second semiconductor wafer comprises a plurality of second semiconductor units each having a set of second conductive interconnect structures extending through the second semiconductor wafer; aligning vertically the second semiconductor wafer with the first semiconductor wafer to stack them together; bonding each of the second semiconductor units with one of the first semiconductor units by using hybrid bonding such that the second top dielectric layer and the set of second conductive interconnect structures of the second semiconductor unit are aligned vertically and bonded with the first top dielectric layer and the set of first conductive interconnect structures of the first semiconductor unit, respectively; singulating the plurality of first semiconductor units of the first semiconductor wafer and the plurality of second semiconductor units of the second semiconductor wafer into a plurality of first semiconductor dice and a plurality of second semiconductor dice such that each of the first semiconductor dice is bonded with one of the second semiconductor dice to form a plurality of bilayer interconnect sub-stacks; testing each of the plurality of bilayer interconnect sub-stacks to sort out qualified bilayer interconnect sub-stacks from the plurality of bilayer interconnect sub-stacks; and bonding at least two of the qualified bilayer interconnect sub-stacks together to form the interconnect stack.

According to another aspect of the present application, an interconnect stack is provided. The interconnect stack comprises a first bilayer interconnect sub-stack and a second bilayer interconnect sub-stack bonded together, wherein each of the first and second bilayer interconnect sub-stacks comprises: a first semiconductor die having at its top side a first top dielectric layer and at its bottom side a first bottom dielectric layer, and a set of first conductive interconnect structures extending through the first semiconductor die; and a second semiconductor die having at its top side a second top dielectric layer and at its bottom side a second bottom dielectric layer, and a set of second conductive interconnect structures extending through the second semiconductor die; and wherein the first semiconductor die is bonded onto the second semiconductor die using hybrid bonding such that the first top dielectric layer and the set of first conductive interconnect structures of the first semiconductor die are aligned vertically and bonded with the second top dielectric layer and the set of second conductive interconnect structures of the second semiconductor die, respectively.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain the principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIGS. 1A to 1K illustrate various steps of a method for forming an interconnect stack according to a first embodiment of the present application.

FIG. 2 illustrates a singulating step of first semiconductor units in a method for forming an interconnect stack according to a second embodiment of the present application.

FIGS. 3A to 3D illustrate various steps of a method for forming an interconnect stack according to a third embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As mentioned above, electronic modules such as wafers or chips may be stacked and bonded together by a hybrid bonding process to form an interconnect stack with multiple functionalities. However, for an interconnect stack incorporating multiple layers of electronic modules, the stacking and hybrid bonding of various layers of electronic modules such as interconnect vias may cause potential challenges of alignment precision. For example, in some cases, the various layers of the electronic modules are stacked and bonded at once to form the interconnect stack. Once the stacking and hybrid bonding between any two of the electronic modules induces unsatisfactory defects, the whole interconnect stack should be discarded. This may result in a limited yield of the interconnect stacks and a high cost of the fabrication process.

To address the above issue, a method for forming an interconnect stack is provided according to some embodiments of the present application. The method includes respectively bonding a plurality of first semiconductor units within a first semiconductor wafer and a plurality of second semiconductor dice through hybrid bonding. Next, a singulating process is conducted to the first semiconductor wafer to form a plurality of bilayer interconnect sub-stacks each including a first semiconductor die and a second semiconductor die bonded thereon. Afterwards, each of the bilayer interconnect sub-stacks is tested to sort out qualified bilayer interconnect sub-stacks. At least two of the qualified bilayer interconnect sub-stacks are then bonded together to form the interconnect stack. Therefore, this method not only utilizes a hybrid bonding process to form bilayer interconnect sub-stacks with high bonding quality, but also implements a testing process to sort out qualified bilayer interconnect sub-stacks before further stacking them together. These procedures may help to solve challenges of alignment precision when multiple layers of semiconductor dice are stacked and bonded together, which result in an improved yield of the interconnect stacks and a lower cost of the fabrication process.

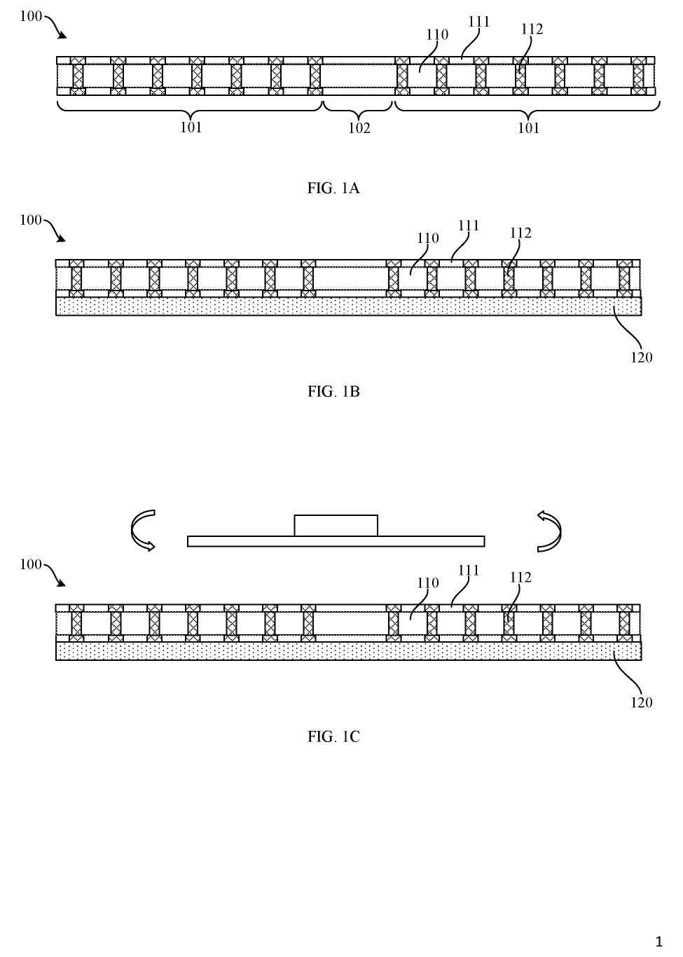

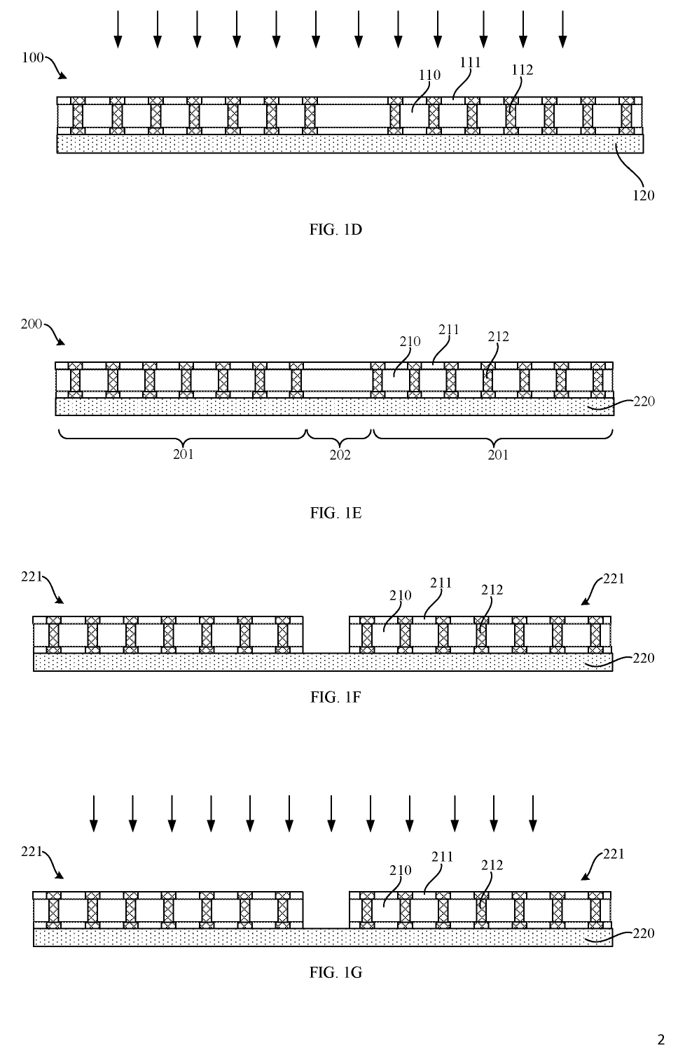

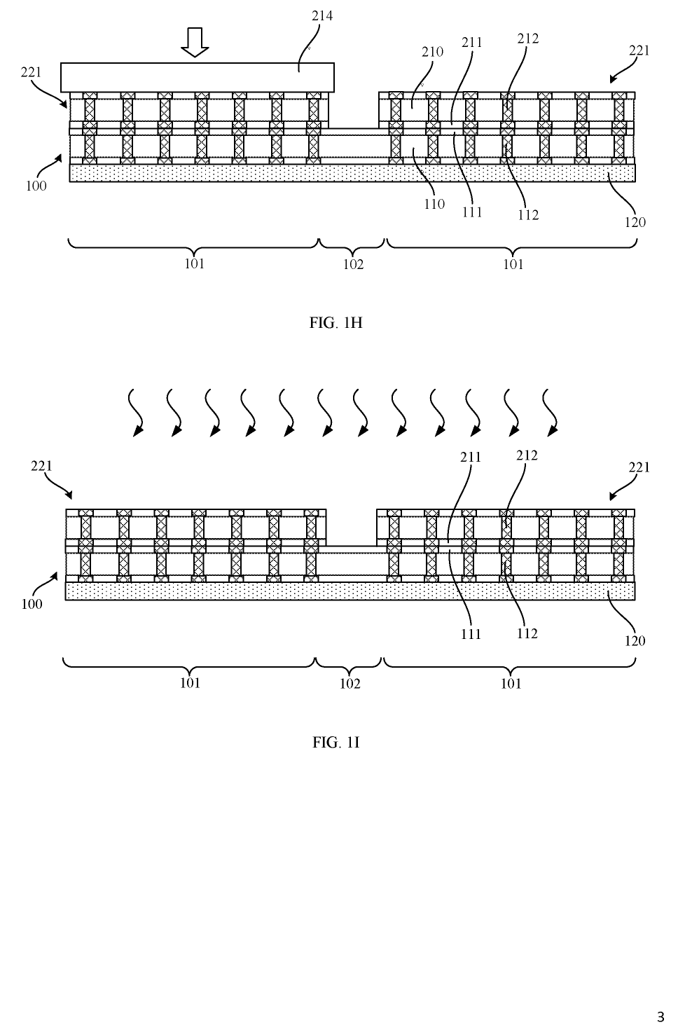

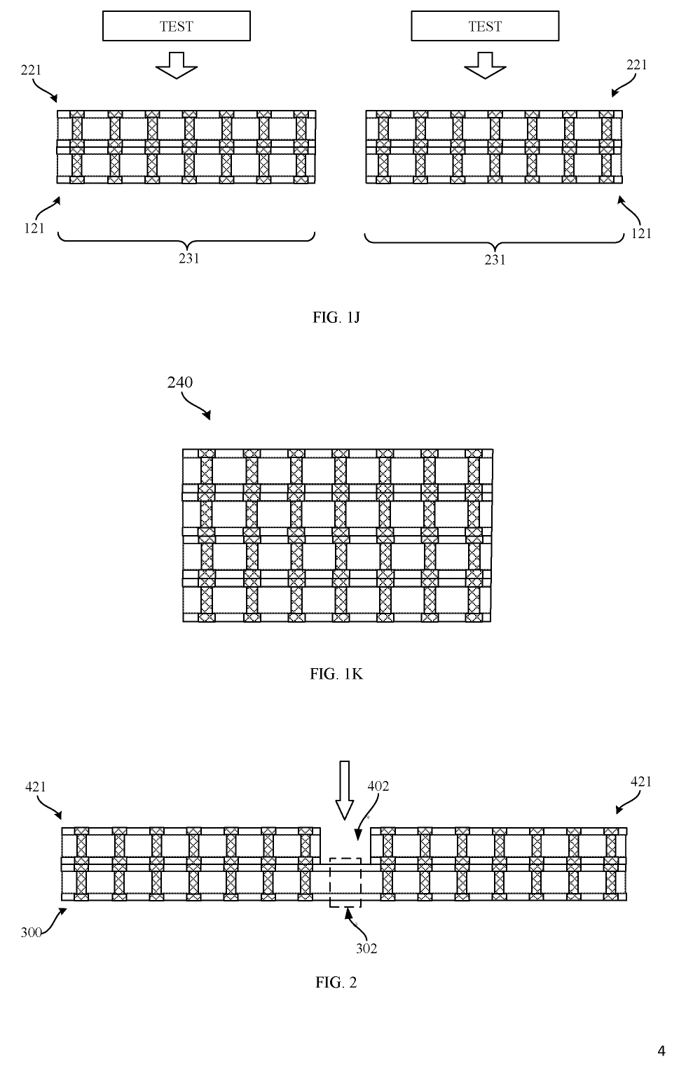

FIGS. 1A to 1K illustrate an interconnect stack according to a first embodiment of the present application.

As shown in FIG. 1A, a first semiconductor wafer 100 is provided. The first semiconductor wafer 100 includes a first wafer body 110 having a top surface facing upward in the direction shown in FIG. 1A. The first wafer body 110 also includes a bottom surface opposite to the top surface. In some embodiments, the first wafer body 110 may include silicon or other semiconductor materials that are suitable for hybrid bonding. In some embodiments, the first semiconductor wafer 100 may be finished with front-end-of-line (FEOL) processes and back-end-of-line (BEOL) process.

Furthermore, the first semiconductor wafer 100 may also include a first top dielectric layer 111 on the top surface of the first wafer body 110 and a first bottom dielectric layer on the bottom surface of the first wafer body 110. In this way, an exposed surface of the first top dielectric layer 111 may be referred to as a top side of the first semiconductor wafer 100, and an exposed surface of the first bottom dielectric layer may be referred to as a bottom side of the first semiconductor wafer 100. In some embodiments, the first top dielectric layer 111 and the first bottom dielectric layer may include silicon oxide, silicon oxynitride or polymer.

In addition, the first semiconductor wafer 100 may include a plurality of first semiconductor units 101. In some embodiments, the first semiconductor wafer 100 further includes a plurality of first saw regions 102, and each of the first saw regions 102 is located between two adjacent first semiconductor units 101. That is, the first semiconductor units 101 and the first saw regions 102 may be different portions of the first semiconductor wafer 100. The first saw regions 102 may be dummy zones without functional modules, which may be designed for singulation in a subsequent process. In some embodiments, the first semiconductor units 101 may have an identical structure. In some other embodiments, the first semiconductor units 101 may be different from each other.

In the embodiment shown in FIG. 1A, each of the first semiconductor units 101 may further include a set of first conductive interconnect structures 112 extending through the first semiconductor wafer 100. In other words, the first conductive interconnect structures 112 may extend through the first top dielectric layer 111, the first wafer body 110 and the first bottom dielectric layer to expose top surfaces and bottom surfaces of the first conductive interconnect structures 112 from a top surface of the first top dielectric layer 111 and a bottom surface of the first bottom dielectric layer, respectively. It should be noted that the first conductive interconnect structures 112 may not be formed within the first saw regions 102. In some other embodiments, multiple sets of conductive pads can be formed on the top and bottom sides of the first semiconductor wafer 100 for the mounting of the first semiconductor units 101. It can be appreciated that the multiple sets of conductive pads may be exposed portions of the plurality sets of first conductive interconnect structures 112 formed within the first semiconductor wafer 100. For example, the multiple sets of conductive pads may be portions of the plurality sets of first conductive interconnect structures 112 which are embedded within the first top dielectric layer 111 and the first bottom dielectric layer. In some embodiments, the first conductive interconnect structures 112 may include metal, such as copper.

Next, as shown in FIG. 1B, a carrier 120 may be attached to the bottom side of the first semiconductor wafer 100. The carrier 120 may be used as a mechanical support during a subsequent surface treatment process and a hybrid bonding process of the first semiconductor wafer 100. In some embodiments, an adhesive may be applied between the bottom side of the first semiconductor wafer 100 and a top side of the carrier 120.

Next, as shown in FIG. 1C, a top portion of the first semiconductor wafer 100, including a top portion of the first top dielectric layer 111 and top portions of the first conductive interconnect structures 112, may be grinded to form a relatively flat top surface of the first semiconductor wafer 100. In some embodiments, a metal oxide layer may be formed on the top surfaces of the first conductive interconnect structures 112 which may adversely influence hybrid bonding. As such, the grinding process may remove the metal oxide layer to prepare the first semiconductor wafer 100 for a subsequent bonding process. In some embodiments, a chemical mechanical polishing (CMP) process may be implemented to grind the top portion of the first semiconductor wafer 100. During the grinding process, a grinding fluid may be applied to the top side of the first semiconductor wafer 100 to improve lubrication between the wafer 100 and the grinding head, thereby facilitating the grinding of the first semiconductor wafer 100. A corrosive liquid may also be included in the grinding fluid to enhance the grinding efficiency. In some other embodiments, the grinding process, for example, the CMP process, may result in a flat top surface of the first top dielectric layer 111 while achieving a slight recess (e.g., in a scale of a few nanometers) for the first conductive interconnect structures 112. This height difference between the top surface of the first top dielectric layer 111 and the top surfaces of the first conductive interconnect structures 112 relative to the carrier 120 may result from a difference in material composition of the first top dielectric layer 111 and the first conductive interconnect structures 112. In addition, the first semiconductor wafer 100 may also be cleaned with deionized water throughout the grinding process, which helps prevent undesired surface contamination.

Next, as shown in FIG. 1D, a surface treatment process, for example, a plasma surface activation process is implemented to the top surface of the first semiconductor wafer 100 to prepare the top surface of the first semiconductor wafer 100 for the subsequent bonding process.

As shown in FIG. 1E, a second semiconductor wafer 200 is provided. In some embodiments, the first semiconductor wafer 100 and the second semiconductor wafer 200 may include a memory chip such as High Bandwidth Memory (HBM) or Dynamic Random Access Memory (DRAM).

The second semiconductor wafer 200 has a similar structure and composition with the first semiconductor wafer 100. To be more specific, the second semiconductor wafer 200 includes a second wafer body 210 having a top surface facing upward in the direction shown in FIG. 1E. The second wafer body 210 also includes a bottom surface opposite to the top surface. The second semiconductor wafer 200 may also include a second top dielectric layer 211 on the top surface of the second wafer body 210 and a second bottom dielectric layer on the bottom surface of the second wafer body 210. Furthermore, the second semiconductor wafer 200 may include a plurality of second semiconductor units 201 and a plurality of second saw regions 202. Each of the second saw regions 202 is located between two adjacent second semiconductor units 201. Additionally, each of the second semiconductor units 201 may further include a set of second conductive interconnect structures 212 extending through the second semiconductor wafer 200. Next, an additional carrier 220 is attached to the bottom side of the second semiconductor wafer 200. Next, a top portion of the second semiconductor wafer 200 may be grinded, for example, by a CMP process, to form a relatively flat top surface of the second semiconductor wafer 200.

Next, as shown in FIG. 1F, the plurality of second semiconductor units 201 are singulated from the second semiconductor wafer 200 as a plurality of second semiconductor dice 221. In particular, the second semiconductor units 201 can be singulated at the second saw regions 202 using a saw blade, a laser cutting tool, or by a plasma dicing process, for example. Next, as shown in FIG. 1G, a surface treatment process, for example, plasma surface activation is implemented to the top surfaces of the second semiconductor dice 221 to prepare the top surfaces for a subsequent bonding process. In some other embodiments, the grinding process can be implemented after the singulation process of the second semiconductor wafer 200 to improve planarization of the semiconductor dice especially after the singulation process because fragments or debris may be generated during the singulation process.

In some preferred embodiments, the first semiconductor wafer 100 and the second semiconductor wafer 200 may be grinded simultaneously, and the surfaces of the first semiconductor wafer 100 and the second semiconductor dices 221 may be activated simultaneously. As such, the first semiconductor wafer 100 and the second semiconductor dice 221 may have a similar surface condition for the subsequent bonding process. It can also be appreciated that the grinding process and/or the surface treatment process of the first semiconductor wafer 100 and the second semiconductor wafer 200/dices 221 can be implemented sequentially.

Next, as shown in 1H, the second semiconductor dice 221 are flipped over with their top surfaces facing the top surface of the first semiconductor wafer 100. Then each of the second semiconductor dice 221 is vertically aligned with and placed onto one of the first semiconductor units 101 of the first semiconductor wafer 100 such that they are stacked together. In particular, each set of first conductive interconnect structures 112 included within a respective first semiconductor unit 101 are vertically aligned with one set of second conductive interconnect structures 212 included within a respective second semiconductor die 221. In some embodiments, an alignment mark may be formed on the first semiconductor units 101 and/or the second semiconductor dice 221 to guarantee precise alignment between the plurality sets of first conductive interconnect structures 112 and the plurality sets of second conductive interconnect structures 212. In addition, the top surfaces of the first and second top dielectric layers 111, 211 are in direct contact with each other.

Next, a hybrid bonding process is implemented to bond together each of the second semiconductor dice 221 with one of the first semiconductor units 101. In particular, the first top dielectric layer 111 of the first semiconductor wafer 100 is bonded with the second top dielectric layer 211, and the set of first conductive interconnect structures 112 of each of the first semiconductor units 101 are aligned vertically and bonded with the set of second conductive interconnect structures 212 of one of the second semiconductor dice 221. Details of the hybrid bonding process are illustrated in FIGS. 1H and 1I.

As shown in FIG. 1H, in some embodiments, after placing the second semiconductor dice 221 onto the respective first semiconductor units 101, the second semiconductor dice 221 are pressed against the first semiconductor units 101 by a bonding head 214. During this process, adherence occurs between the grinded top surfaces of the first semiconductor units 101 and the second semiconductor dice 221. This results in a strong surface-to-surface attraction and closes gaps from a center region to an edge of each pair of aligned first semiconductor unit 101 and second semiconductor die 221. This process may be conducted at a room temperature to guarantee a direct and close contact between the top surfaces of the first semiconductor units 101 and the second semiconductor dice 221, which serve as bonding surfaces of a subsequently formed hybrid bonding structure.

Next, as shown in FIG. 1I, an annealing process is implemented to the second semiconductor dice 221 and the first semiconductor units 101. A fusion bonding may be established between the sets of first conductive interconnect structures 112 and the sets of second conductive interconnect structures 212 to form a strong metal-to-metal interconnection. Also, the first and second top dielectric layers 111, 211 may be expanded to allow for a closer contact between each other, thereby forming a sufficient bonding therebetween. In this way, a permanent hybrid bonding, which combines dielectric-to-dielectric bonding between the first and second top dielectric layers 111, 211 and metal-to-metal bonding between the first and second conductive interconnect structures 112, 212 may be formed. In some embodiments, the annealing process is conducted at a temperature ranging between 250°C and 400°C, and may last for a duration between 20 minutes to 230 minutes.

It can be appreciated that the above steps and conditions for the hybrid bonding is exemplary and not mandatory. In some other embodiments, the first and second conductive interconnect structures 112, 212 may have slight recesses at their top surfaces, and their top surfaces may be lower than the top surfaces of the first and second top dielectric layers 111, 211. In these cases, the first and second top dielectric layers 111, 211 may establish initial bonding when they are in direct contact with each other at a room temperature. Next, a heating process may be applied to close the gap between the first and second conductive interconnect structures 112, 212 since the coefficient of thermal expansion of the first and second conductive interconnect structures 112, 212 are larger than that of the first and second top dielectric layers 111, 211. Afterwards, an annealing process is conducted to form the hybrid bonding.

Next, as shown in FIG. 1J, the plurality of first semiconductor units 101 of the first semiconductor wafer 100 are singulated into a plurality of first semiconductor dice 121. Therefore, each of the first semiconductor dice 121 is bonded with one of the second semiconductor dice 221. In this way, a plurality of bilayer interconnect sub-stacks 231 are formed, and each of them includes a first semiconductor die 121 and a second semiconductor die 221 bonded thereon. The plurality of first semiconductor units 101 may be singulated along the plurality of first saw regions 102 of the first semiconductor wafer 100.

In this embodiment, the hybrid bonding allows for a direct connection between the first and second semiconductor dice 121, 221, which enables improved performance and reduces power consumption of subsequently formed electronic devices. In addition, interconnects with extremely fine pitch are used to establish electrical connections between these semiconductor dice.

Next, a testing process is conducted to each of the plurality of bilayer interconnect sub-stacks 231. During this process, each of the plurality of bilayer interconnect sub-stacks 231 may be subject to various types of electrical or non-electrical tests so as to test their characteristics and defects, e.g., a lack of alignment precision between the first and second semiconductor dice 121, 221. In this way, qualified bilayer interconnect sub-stacks which have satisfactory bonding quality and electrical performance are sorted out, while the non-qualified

bilayer interconnect sub-stacks which have problematic bonding defects may be discarded from subsequent processes. Next, two of the qualified bilayer interconnect sub-stacks are further bonded together. In some embodiments, the two of the qualified bilayer interconnect sub-stacks are bonded by hybrid bonding which has a similar structure and a similar formation process as that illustrated in FIGS. 1H and 1I and will not be elaborated here. Therefore, an interconnect stack 240 is so formed, as shown in 1K.

In some embodiments, more qualified bilayer interconnect sub-stack(s) 231 may further be stacked onto the interconnect stack 240 to form a larger interconnect stack with six or more layers, for example, by hybrid bonding. It can also be appreciated that a testing and sorting process may be conducted to the so formed interconnect stack after each of the bonding process.

In some other embodiments, after a plurality of four-layer interconnect stacks 240 are formed, another testing process may be conducted to each of the four-layer interconnect stacks to sort out qualified ones. At least two qualified four-layer interconnect stacks 240 are further bonded together, for example, by hybrid bonding, thereby forming a highly-integrated interconnect stack with multiple layers.

In this embodiment, the testing process is implemented after two semiconductor dice are vertically aligned and bonded by hybrid bonding. In this way, the bilayer interconnect sub-stacks which have defects and poor electrical performance may be identified and discarded at an early stage, thereby resulting in minimum loss in subsequent fabrication of interconnect stacks with more layers. In some preferred embodiments, the testing and sorting process may be implemented after each hybrid bonding process is conducted between two semiconductor dice or two interconnect sub-stacks. Therefore, the finally formed interconnect stacks may have an improved yield and a reduce cost.

In some embodiments, the plurality of first semiconductor dice 121 may have a similar size as that of the plurality of second semiconductor dice 221. That is, the plurality of second saw regions 202 may have a similar size as that of the plurality of first saw regions 102. In some alternative embodiments, the plurality of second semiconductor dice 221 may have a smaller size than that of the plurality of first semiconductor dice 121, and the plurality of second saw regions 202 may have a larger size than that of the plurality of first saw regions 102. An example of such alternative embodiment is provided below.

FIG. 2 illustrates a singulating step of first semiconductor units in a method for forming an interconnect stack according to a second embodiment of the present application.

As shown in FIG. 2, a first semiconductor wafer 300 and a second semiconductor wafer are provided. The first semiconductor wafer 300 may include a plurality of first semiconductor units and a plurality of first saw regions 302. Each of the first saw regions 302 is located between two adjacent first semiconductor units. Similarly, the second semiconductor wafer may include a plurality of second semiconductor units and a plurality of second saw regions. The plurality of second saw regions have a larger size than that of the plurality of first saw regions 302, and the plurality of second semiconductor units have a smaller size than that of the plurality of first semiconductor units.

In this embodiment, the plurality of second semiconductor units of the second semiconductor wafer are singulated along the second saw regions of the second semiconductor wafer. Therefore, a plurality of second semiconductor dice 421 are formed with relatively large saw gaps 402, each of which is located between two adjacent second semiconductor dice 421.

Therefore, as shown in FIG. 2, in a singulation process to separate the first semiconductor wafer 300 into a plurality of first semiconductor dice, the singulation is conducted to the first semiconductor wafer 300 at the exposed saw gaps 402 and along the first saw regions 302 using a saw blade, a laser cutting tool or by a plasma dicing process, for example. Since the second saw regions have a larger size than the plurality of first saw regions 302, target areas for the singulation process on the first semiconductor wafer 300 are smaller than the respective exposed saw gaps 402 above them. As such, when the singulation process is conducted along the first saw regions, the second semiconductor dice 421 may not be affected due to the relatively large saw gaps 402 between adjacent second semiconductor dice 421.

Other details of the method for forming the interconnect stack in the second embodiment may be the same as those of the method illustrated in FIGS. 1A to 1K, which will not be elaborated here. Finally, an interconnect stack including bonded bilayer interconnect sub-stacks is formed, and each of the bilayer interconnect sub-stacks may have a semiconductor die with a smaller size bonded with another semiconductor die with a larger size.

In some alternative embodiments, the interconnect stack may include both hybrid bonding and solder bumps bonding to bond multiple layers of semiconductor dice together, which will be elaborated below.

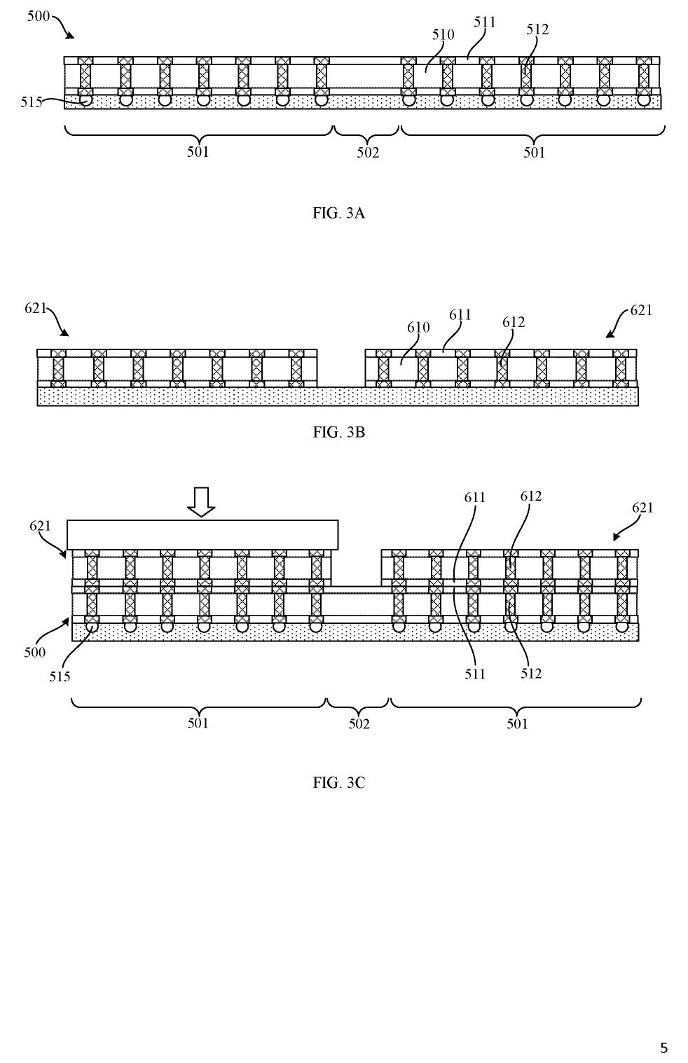

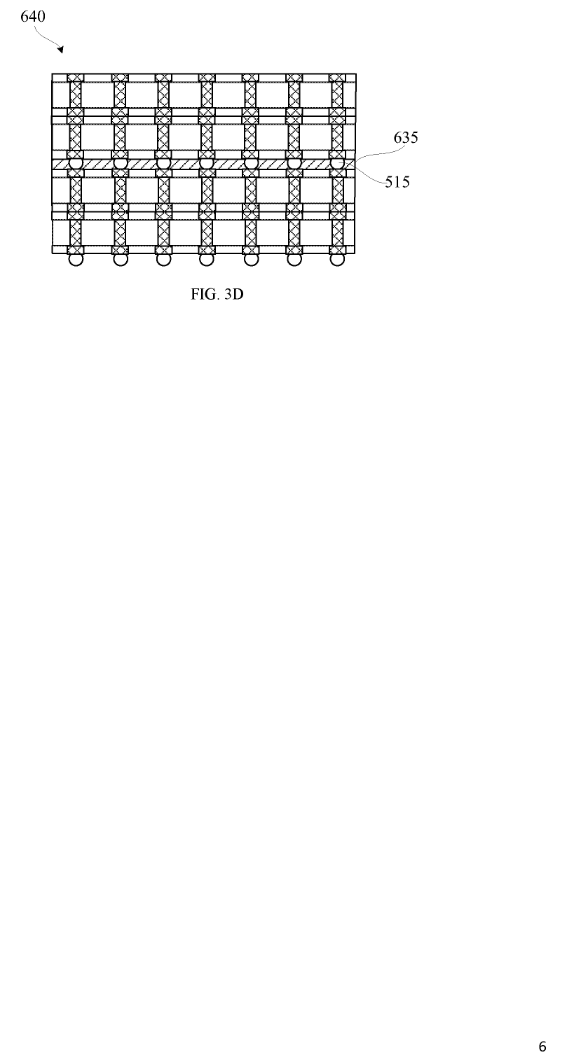

FIGS. 3A to 3D illustrate various steps of a method for forming an interconnect stack according to a third embodiment of the present application.

As shown in FIG. 3A, a first semiconductor wafer 500 is provided. The first semiconductor wafer 500 includes a first wafer body 510 having a top surface facing upward in the direction shown in FIG. 3A. The first wafer body 510 also includes a bottom surface opposite to the top surface. The first semiconductor wafer 500 includes a first top dielectric layer 511 on the top surface of the first wafer body 510 and a first bottom dielectric layer on the bottom surface of the first wafer body 510. Furthermore, the first semiconductor wafer 500 includes a plurality of first semiconductor units 501 and a plurality of first saw regions 502. Each of the first saw regions 502 is located between two adjacent first semiconductor units 501. Each of the first semiconductor units 501 may further include a set of first conductive interconnect structures 512 extending through the first semiconductor wafer 500.

Additionally, each of the first semiconductor units 501 may further include a plurality of solder bumps 515, each of which is formed on a bottom surface of one of the first conductive interconnect structures 512. In some embodiments, the solder bumps 515 may be exposed from the first bottom dielectric layer. It can also be appreciated that at least a portion of the solder bumps 515 may be embedded within the first bottom dielectric layer while at least a portion of bottom surfaces of the solder bumps 515 is still exposed from the first bottom dielectric layer for an external electrical connection.

Next, a carrier is attached to a bottom side of the first semiconductor wafer 500. In some preferred embodiments, the carrier may include a flexible material such as silicone, which can be deformed to accommodate the solder bumps 515.

As shown in FIG. 3B, a second semiconductor wafer is provided. The second semiconductor wafer includes a second wafer body 610 having a top surface and a bottom surface opposite to the top surface. The second semiconductor wafer includes a second top dielectric layer 611 on the top surface of the second wafer body 610 and a second bottom dielectric layer on the bottom surface of the second wafer body 610. Furthermore, the second semiconductor wafer includes a plurality of second semiconductor units and a plurality of second saw regions. Each of the second semiconductor units may further include a set of second conductive interconnect structures 612 extending through the second semiconductor wafer. Next, the plurality of second semiconductor units are singulated from the second semiconductor wafer as a plurality of second semiconductor dice 621.

It can be appreciated that a grinding process and a plasma surface activation process may be implemented to the first semiconductor wafer 500 and the second semiconductor wafer /dice at suitable steps, which may be similar to those illustrated in FIGS. 1C, 1D, or 1G .

Next, as shown in FIG. 3C, a hybrid bonding process is implemented to bond together each of the second semiconductor dice 621 with one of the first semiconductor units 501. In particular, the first top dielectric layer 511 is aligned vertically and bonded with the second top dielectric layer 611, and the sets of first conductive interconnect structures 512 are aligned vertically and bonded with the sets of second conductive interconnect structures 612.

Afterwards, the plurality of first semiconductor units 501 of the first semiconductor wafer 500 are singulated into a plurality of first semiconductor dice. Therefore, a plurality of bilayer interconnect sub-stacks are formed, each of which includes a first semiconductor die with exposed solder bumps 515 and a second semiconductor die 621 bonded thereon by hybrid bonding. A testing process is implemented to sort out qualified bilayer interconnect sub-stacks. Then at least two of the qualified bilayer interconnect sub-stacks are stacked together with the solder bumps 515 disposed therebetween. Afterwards, a reflowing process may be conducted to the solder bumps 515 so as to establish an electrical connection between the two adjacent qualified bilayer interconnect sub-stacks. Therefore, an interconnect stack 640 with hybrid bonding and solder bumps bonding is formed (as illustrated in 3D), which allows for improved flexibility of an electrical connection pattern and layout between the stacked semiconductor dice according to actual requirements.

Finally, an encapsulating layer 635 is formed at least between two adjacent qualified bilayer interconnect sub-stacks to encapsulate the plurality of solder bumps 515.

Apart from the die-to-wafer hybrid bonding process described with reference to the above embodiments, a wafer-to-wafer bonding process may also be used to form the interconnect stack, which will be elaborated below.

To be more specific, a first semiconductor wafer and a second semiconductor wafer may first be bonded by hybrid bonding such that each second semiconductor unit is vertically aligned and bonded with one respective first semiconductor unit. Afterwards, the first semiconductor units of the first semiconductor wafer and the second semiconductor units of the second semiconductor wafer are singulated into a plurality of first semiconductor dice and a plurality of second semiconductor dice simultaneously, so as to form a plurality of bilayer interconnect sub-stacks. Next, each of the plurality of bilayer interconnect sub-stacks is tested to sort out qualified bilayer interconnect sub-stacks from the plurality of bilayer interconnect sub-stacks. Finally, at least two of the qualified bilayer interconnect sub-stacks are bonded together to form the interconnect stack.

In some other embodiments, a die-to-die bonding process may also be used to form the interconnect stack. To be more specific, firstly, both the first semiconductor wafer and the second semiconductor wafer are singulated into first semiconductor dice and second semiconductor dice. Afterwards, each of the first semiconductor dice is bonded with one of the second semiconductor dice such that bilayer interconnect sub-stacks are formed. Next, each of the bilayer interconnect sub-stacks is tested to sort out qualified bilayer interconnect sub-stacks. Finally, at least two of the qualified bilayer interconnect sub-stacks are bonded together to form the interconnect stack.

While the exemplary interconnect stack and the method for forming an interconnect stack of the present application are described in conjunction with corresponding figures, it will be understood by those skilled in the art that modifications and adaptations to the interconnect stack and the method may be made without departing from the scope of the present invention.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A method for forming an interconnect stack, comprising:
providing a first semiconductor wafer having at its top side a first top dielectric layer and at its bottom side a first bottom dielectric layer, wherein the first semiconductor wafer comprises a plurality of first semiconductor units each having a set of first conductive interconnect structures extending through the first semiconductor wafer;
providing a second semiconductor wafer having at its top side a second top dielectric layer and at its bottom side a second bottom dielectric layer, wherein the second semiconductor wafer comprises a plurality of second semiconductor units each having a set of second conductive interconnect structures extending through the second semiconductor wafer;
singulating the plurality of second semiconductor units of the second semiconductor wafer into a plurality of second semiconductor dice;
aligning vertically each of the second semiconductor dice with one of the first semiconductor units of the first semiconductor wafer to stack them together;
bonding each of the second semiconductor dice with one of the first semiconductor units by using hybrid bonding such that the second top dielectric layer and the set of second conductive interconnect structures of the second semiconductor die are aligned vertically and bonded with the first top dielectric layer and the set of first conductive interconnect structures of the first semiconductor unit, respectively;
singulating the plurality of first semiconductor units of the first semiconductor wafer into a plurality of first semiconductor dice such that each of the first semiconductor dice is bonded with one of the second semiconductor dice to form a plurality of bilayer interconnect sub-stacks;
testing each of the plurality of bilayer interconnect sub-stacks to sort out qualified bilayer interconnect sub-stacks from the plurality of bilayer interconnect sub-stacks; and
bonding at least two of the qualified bilayer interconnect sub-stacks together to form the interconnect stack.

2. The method of claim 1, wherein the first semiconductor wafer further comprises a plurality of first saw regions, each of which is located between two adjacent first semiconductor units; and the second semiconductor wafer further comprises a plurality of second saw regions, each of which is located between two adjacent second semiconductor units.

3. The method of claim 2, wherein the plurality of second saw regions have a larger size than that of the plurality of first saw regions, and the plurality of second semiconductor units have a smaller size than that of the plurality of first semiconductor units.

4. The method of claim 2, wherein singulating the plurality of second semiconductor units of the second semiconductor wafer into a plurality of second semiconductor dice comprises: singulating the plurality of second semiconductor units along the plurality of second saw regions of the second semiconductor wafer; and
singulating the plurality of first semiconductor units of the first semiconductor wafer into a plurality of first semiconductor dice comprises: singulating the plurality of first semiconductor units along the plurality of first saw regions of the first semiconductor wafer.

5. The method of claim 1, wherein before aligning vertically each of the second semiconductor dice with one of the first semiconductor units of the first semiconductor wafer to stack them together, the method further comprises:
implementing plasma surface activation to the top side of the first semiconductor wafer; and implementing plasma surface activation to top surfaces of the second semiconductor dice.

6. The method of claim 5, wherein bonding each of the second semiconductor dice with one of the first semiconductor units further comprises:
bonding the top surface of each of the second semiconductor dice onto a top surface of one of the first semiconductor units.

7. The method of claim 1, wherein bonding each of the second semiconductor dice with one of the first semiconductor units by using hybrid bonding comprises:
pressing the second semiconductor dice against the first semiconductor units; and
implementing an annealing process to the second semiconductor dice and the first semiconductor units.

8. The method of claim 1, wherein bonding at least two of the qualified bilayer interconnect sub-stacks together comprises: bonding the at least two of the qualified bilayer interconnect sub-stacks by using hybrid bonding.

9. The method of claim 1, wherein each of the first semiconductor units further comprises: a plurality of solder bumps each formed on a bottom surface of one of the first conductive interconnect structures; and
bonding at least two of the qualified bilayer interconnect sub-stacks together comprises: bonding the at least two of the qualified bilayer interconnect sub-stacks together by soldering.

10. The method of claim 9, wherein after bonding the at least two of the qualified bilayer interconnect sub-stacks together, the method further comprises: forming an encapsulating layer at least between two adjacent qualified bilayer interconnect sub-stacks to encapsulate the plurality of solder bumps.

11. A method for forming an interconnect stack, comprising:
providing a first semiconductor wafer having at its top side a first top dielectric layer and at its bottom side a first bottom dielectric layer, wherein the first semiconductor wafer comprises a plurality of first semiconductor units each having a set of first conductive interconnect structures extending through the first semiconductor wafer;
providing a second semiconductor wafer having at its top side a second top dielectric layer and at its bottom side a second bottom dielectric layer, wherein the second semiconductor wafer comprises a plurality of second semiconductor units each having a set of second conductive interconnect structures extending through the second semiconductor wafer;
aligning vertically the second semiconductor wafer with the first semiconductor wafer to stack them together;
bonding each of the second semiconductor units with one of the first semiconductor units by using hybrid bonding such that the second top dielectric layer and the set of second conductive interconnect structures of the second semiconductor unit are aligned vertically and bonded with the first top dielectric layer and the set of first conductive interconnect structures of the first semiconductor unit, respectively;
singulating the plurality of first semiconductor units of the first semiconductor wafer and the plurality of second semiconductor units of the second semiconductor wafer into a plurality of first semiconductor dice and a plurality of second semiconductor dice such that each of the first semiconductor dice is bonded with one of the second semiconductor dice to form a plurality of bilayer interconnect sub-stacks;
testing each of the plurality of bilayer interconnect sub-stacks to sort out qualified bilayer interconnect sub-stacks from the plurality of bilayer interconnect sub-stacks; and
bonding at least two of the qualified bilayer interconnect sub-stacks together to form the interconnect stack.

12. An interconnect stack, comprising:
a first bilayer interconnect sub-stack and a second bilayer interconnect sub-stack bonded together, wherein each of the first and second bilayer interconnect sub-stacks comprises:
a first semiconductor die having at its top side a first top dielectric layer and at its bottom side a first bottom dielectric layer, and a set of first conductive interconnect structures extending through the first semiconductor die; and
a second semiconductor die having at its top side a second top dielectric layer and at its bottom side a second bottom dielectric layer, and a set of second conductive interconnect structures extending through the second semiconductor die; and
wherein the first semiconductor die is bonded onto the second semiconductor die using hybrid bonding such that the first top dielectric layer and the set of first conductive interconnect structures of the first semiconductor die are aligned vertically and bonded with the second top dielectric layer and the set of second conductive interconnect structures of the second semiconductor die, respectively.

13. The interconnect stack of claim 12, wherein the second semiconductor die has a smaller size than that of the first semiconductor die.

14. The interconnect stack of claim 12, wherein the first bilayer interconnect sub-stack and the second bilayer interconnect sub-stack are bonded together through hybrid bonding.

15. The interconnect stack of claim 12, wherein the first bilayer interconnect sub-stack and the second bilayer interconnect sub-stack are bonded together through a plurality of solder bumps.
